(19) United States
(12) Patent Application Publication
(10) Pub. No.: US 2026/0029446 A1
(43) Pub. Date: Jan. 29, 2026

(54) ELECTRICAL CIRCUIT AND METHOD FOR DETERMINING RESISTOR VALUES AND METHOD FOR PROGRAMMING A TURN ON/OFF SPEED OF SWITCH CIRCUITRY

(71) Applicant: Infineon Technologies Austria AG, Villach (AT)

(72) Inventors: Derek BERNARDON, Villach (AT); Thomas LEITNER, Pregarten (AT)

(21) Appl. No.: 19/254,778

(22) Filed: Jun. 30, 2025

(30) Foreign Application Priority Data
Jul. 24, 2024 (DE) 102024121084.2

(51) Int. Cl. G01R 27/14; H03K 17/687

(52) U.S. Cl. CPC G01R 27/14; H03K 17/687

(57) ABSTRACT

An apparatus as discussed herein includes: a first circuit node coupling a first resistor and a second resistor in series between an input voltage source and a reference voltage source; current mirror circuitry coupled to the first circuit node, the current mirror circuitry operative to: i) produce a first mirror current based a first current conveyed through the first resistor, and ii) produce a second mirror current based on a second current conveyed through the second resistor; and measurement circuitry operative to determine resistances of the first resistor and the second resistor via various techniques.

### RELATED APPLICATIONS

This application claims priority to earlier filed German Patent Application Serial Number 102024121084.2, filed on Jul. 24, 2024, the entire teachings of which are incorporated herein by this reference.

### TECHNICAL FIELD

The present disclosure relates to an electrical circuit for reading out resistor values, to a method for reading out resistor values and to a method for programming a turn on and turn off speed of an integrated power switch.

### BACKGROUND

The behavior of a variety of electrical circuits may be adjusted or programmed using resistors with different specific resistance values. For example, a power switch may comprise a driver configured to control a load current. A turn on speed and a turn off speed used by the driver may be programmed with two resistors (one for the turn on speed and one for the turn off speed). Such a programming entails reading out the resistance values of the resistors by means of a readout circuit connected to the resistances. This readout circuit may for example be comprised in a semiconductor chip, wherein the resistors are external to the semiconductor chip and are electrically connected to pins of the semiconductor chip. There may be a limited number of pins available for reading out the resistances. In particular, a single pin may be available to read out the resistances of two resistors. Furthermore, the measurement should be accurate and also fast (the measurement may e.g. be performed during startup prior to turning on of a power transistor which would generate too much noise to make an accurate measurement).

### SUMMARY

This disclosure includes improved electrical circuits for reading out resistor values, improved methods for reading out resistor values, and improved methods for programming a turn on and turn off speed of an integrated power switch may help with solving the above-mentioned and other problems.

Various aspects pertain to a method for measuring digital resistance values, the method comprising: providing a semiconductor chip comprising a first pin and a second pin, the semiconductor chip being configured to be provided with a supply voltage, wherein the first pin is configured to have a first voltage applied, and wherein the second pin is configured to have the first voltage applied or to have a second voltage applied, the first voltage being lower than the supply voltage and the second voltage being non-zero and lower than the first voltage, connecting a first external resistor between the second pin and a reference potential and connecting a second external resistor between the first pin and the second pin, wherein in a first step the first voltage is applied to the second pin and a first current flowing from the second pin through the first external resistor to the reference potential due to the first voltage is mirrored internally to determine, using an analog to digital converter, a first digital resistance value representing a resistance of the first external resistor, wherein in a second step the second voltage is applied to the second pin and a second current flowing through the second pin due to the second voltage and being comprised of a first component current flowing from the first pin through the second resistor to the second pin minus a second component current flowing from the second pin through the first external resistor to the reference potential is mirrored internally and an error correction current is added to the internally mirrored current to determine, using the analog to digital converter, a second digital resistance value representing a resistance of the second external resistor, and wherein the first digital resistance value is used to generate the error correction current.

Various aspects pertain to a method for programming a turn on and turn off speed of an integrated power switch, the method comprising: performing the method for determining electrical resistor values, and programming a turn on slew rate and a turn off slew rate of the integrated power switch using the first and second digital resistance values.

Various aspects pertain to an electrical circuit configured for measuring digital resistance values, the circuit comprising: a semiconductor chip comprising a first and a second pin, wherein the semiconductor chip is configured to be provided with a supply voltage, wherein the first pin is configured to have a first voltage applied, and wherein the second pin is configured to have the first voltage applied or to have a second voltage applied, the first voltage being lower than the supply voltage and the second voltage being non-zero and lower than the first voltage, a first external resistor connected between the second pin and a reference potential and a second external resistor connected between the first pin and the second pin, wherein the electrical circuit is configured to have in a first step the first voltage applied to the second pin and to mirror internally a first current flowing from the second pin through the first external resistor to the reference potential due to the first voltage in order to determine, using an analog to digital converter, a first digital resistance value representing a resistance of the first external resistor, wherein the electrical circuit is configured to have in a second step the second voltage applied to the second pin and to mirror internally a second current flowing through the second pin due to the second voltage and being comprised of a first component current flowing from the first pin through the second resistor to the second pin minus a second component current flowing from the second pin through the first external resistor to the reference potential in order to determine, using the analog to digital converter, a second digital resistance value representing a resistance of the second external resistor, wherein the first digital resistance value is used to generate the error correction current.

Various aspects pertain to an electrical circuit configured for measuring digital resistance values, the circuit comprising: a semiconductor chip comprising a first and a second pin, wherein the semiconductor chip is configured to be provided with a supply voltage, wherein the first pin is configured to have a first voltage applied, and wherein the second pin is configured to have the first voltage applied or to have a second voltage applied, the first voltage being lower than the supply voltage and the second voltage being equal to a reference potential, a first external resistor connected between the second pin and the reference potential and a second external resistor connected between the first pin and the second pin, wherein the electrical circuit is configured to have in a first step the first voltage applied to the second pin and to mirror internally a first current flowing from the second pin through the first external resistor to the reference potential due to the first voltage in order to determine, using an analog to digital converter, a first digital resistance value representing a resistance of the first external resistor, wherein the electrical circuit is configured to have in a second step the second voltage applied to the second pin and to mirror internally a second current flowing from the first pin through the second resistor to the second pin due to the second voltage in order to determine, using the analog to digital converter, a second digital resistance value representing a resistance of the second external resistor.

Various aspects pertain to a method for measuring digital resistance values, the method comprising: providing a semiconductor chip comprising a first pin and a second pin, the semiconductor chip being configured to be provided with a supply voltage, wherein the first pin is configured to have a first voltage applied, and wherein the second pin is configured to have the first voltage applied or to have a second voltage applied, the first voltage being lower than the supply voltage and the second voltage being equal to a reference potential, connecting a first external resistor between the second pin and a reference potential and connecting a second external resistor between the first pin and the second pin, wherein in a first step the first voltage is applied to the second pin and a first current flowing from the second pin through the first external resistor to the reference potential due to the first voltage is mirrored internally to determine, using an analog to digital converter, a first digital resistance value representing a resistance of the first external resistor, wherein in a second step the second voltage is applied to the second pin and a second current flowing from the first pin through the second resistor to the second pin due to the second voltage is mirrored internally to determine, using the analog to digital converter, a second digital resistance value representing a resistance of the second external resistor.

In further examples, the electrical circuit as discussed herein includes: a noise cancellation circuit operative to supply a noise cancellation signal to the second pin.

The noise cancellation circuit can be configured to receive a noise signal; and invert the noise signal to produce the noise cancellation signal.

Additionally, the noise cancellation circuit can be configured to receive the noise signal from the reference potential or other source.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1A to 1C illustrate an electrical circuit configured for measuring digital resistance values. The electrical circuit comprises a semiconductor chip and two external resistors connected to pins of the semiconductor chip.

FIG. 2 illustrates a specific implementation of the electrical circuit schematically shown in FIGS. 1A to 1C.

FIG. 3 illustrates a further specific implementation of the electrical circuit schematically shown in FIGS. 1A to 1C.

FIG. 4 is a flow chart of an exemplary method for measuring digital resistance values. The method may for example be performed using the electrical circuit disclosed with respect to FIGS. 1A to 3.

FIG. 5 is a flow chart of an exemplary method for programming a turn on speed and a turn off speed of an integrated power switch. The method may for example be performed using the electrical circuit disclosed with respect to FIGS. 1A to 3.

FIGS. 6A and 6B illustrate a further example of an electrical circuit configured for measuring digital resistance values.

FIG. 7 is a flow chart of a further exemplary method for measuring digital resistance values. The method may for example be performed using the electrical circuit disclosed with respect to FIGS. 6A and 6B.

FIG. 8 is an example diagram illustrating implementation of noise canceling circuitry as discussed herein.

### DETAILED DESCRIPTION

In the following detailed description, known structures and elements are shown in schematic form in order to facilitate describing one or more aspects of the disclosure. In this regard, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary” is merely meant as an example, rather than the best or optimal.

A power semiconductor chip for e.g. a power switch may be manufactured from specific semiconductor material, for example Si, SiC, SiGe, GaAs, GaN, or from any other semiconductor material, and, furthermore, may contain one or more of inorganic and organic materials that are not semiconductors, such as for example insulators, plastics or metals.

An efficient electrical circuit for reading out resistor values, an efficient method for reading out resistor values and an efficient method for programming a turn on and turn off speed of an integrated power switch may for example reduce material consumption, ohmic losses, chemical waste, etc. and may thus enable energy and/or resource savings. Improved methods and devices, as specified in this description, may thus at least indirectly contribute to green technology solutions, i.e. climate-friendly solutions providing a mitigation of energy and/or resource use.

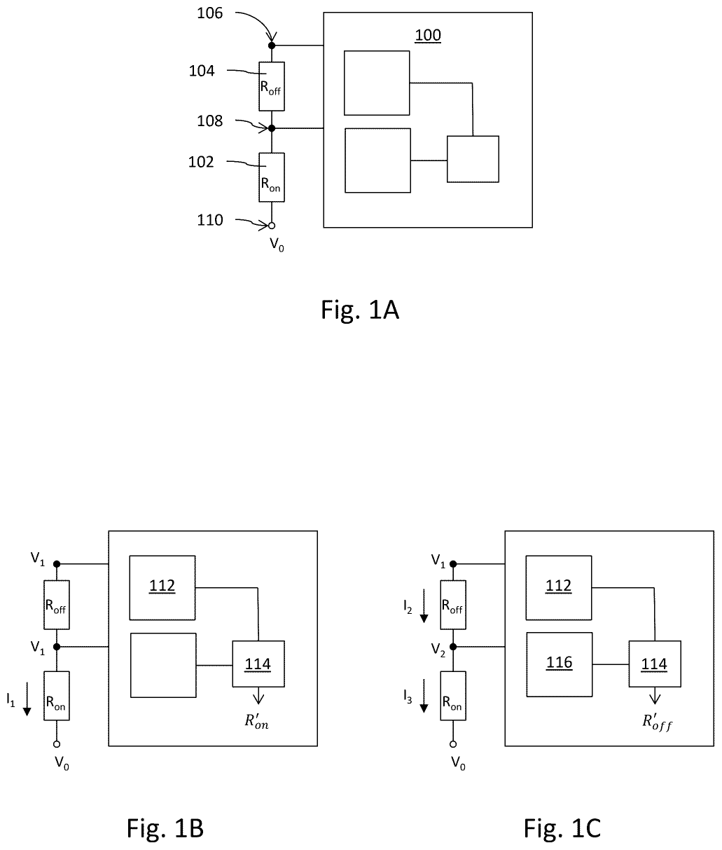

FIG. 1A schematically shows an electrical circuit comprising a semiconductor chip 100, a first external resistor 102 (Rₒₙ) and a second external resistor 104 (R_{off}) electrically connected to each other. The semiconductor chip 100 comprises a first pin 106 and a second pin 108, wherein the first external resistor 102 is connected between the second pin 108 and a reference potential 110 (V₀) and the second external resistor 104 is connected between the first pin 106 and the second pin 108.

The semiconductor chip 100 may be configured to read out a resistance of the first external resistor 102 and a resistance of the second external resistor 104. The electrical circuit comprising semiconductor chip 100 and the external resistors 102, 104 may for example be part of a driver for a power switch, in particular an integrated power switch, wherein the external resistors 102, 104 are used to program a turn on speed (or turn on slew rate) and a turn off speed (or turn off slew rate) for the driver of the power switch. The first external resistor 102 may e.g. be used to program the turn on speed and the second external resistor 104 may e.g. be used to program the turn off speed at which the power switch is driven. Such a power switch may for example comprise a GaN device or a SiC device or a MOSFET device or any other suitable (power) semiconductor device. For practical reasons and/or for cost reasons, such a power switch might not comprise a memory configured to store the resistance values of the external resistors 102, 104 when the respective power stage is not active. It may therefore be necessary to read out the resistances each time the power stage in question is activated.

According to an example, it may be desirable to have 16 different options for individual resistance values, out of which one is an open case, for each of the first and second external resistors 102, 104 (i.e. 256 options for the combination of both external resistors 102, 104). This may mean that the required total accuracy for the readout of the resistances is e.g. about ±7%. Furthermore, there may be a restriction of having not too small of a programming resistor, e.g. a resistor with a resistance greater than 15 kΩ or greater than 20 kΩ as not to consume too much current from a supply voltage when both external resistors 102, 104 are of the smallest value. Additionally, the resistance values should not be too big as not to have too little sense current in order to avoid measurement disturbances due to electromagnetic interference (EMI) and/or noise. For example, the resistance values of the external resistors 102, 104 should not be significantly bigger than e.g. 200 kΩ or 250 kΩ. Assuming for example the use of e96 resistors, which have a linear distribution of resistances of ±1%, which additionally have 1% error due to temperature variation and another 1% for lifetime, this implies that the circuit should be designed to achieve ±4% measurement accuracy within e.g. about 4 μs or even only about 2 μs of measurement time.

According to an example, this measurement is performed during startup, while the supply voltage is rising. Thus, the circuit must be independent of the supply voltage, although it is the supply of the external resistor divider. In addition, speed may be important, as this measurement is performed during startup prior to turning on of a power transistor which would generate too much noise to make an accurate reading.

The semiconductor device may for example comprise or consist of a package and may for example comprise a limited number of pins. It may therefore be desirable to reserve as few pins as possible for reading out the resistances of the external resistors 102, 104. In particular, it may be desirable to read out the resistances using only a single pin. As shown in the following, solely the second pin 108 is used as a readout pin for measuring the resistances of both external resistors 102, 104 and no additional readout pin is required.

During operation, the semiconductor chip 100 may be provided with the supply voltage. Furthermore, during operation a first voltage may be applied to the first pin 106 and the first voltage or a second voltage may be applied to the second pin 108. The first voltage is lower than the supply voltage and the second voltage is different from zero and lower than the first voltage. According to an example, the supply voltage is V_{CC}. According to an example, the first voltage is about 200 mV or more lower than the supply voltage, or about 300 mV or more lower than the supply voltage, or about 1.5V lower than the supply voltage. The semiconductor chip 100 may for example comprise a further pin, wherein the supply voltage is applied to the further pin. According to another example, if no further pin is available, a charge pump could be used to boost V_{CC} from V_{DD}.

According to an example, the first voltage is V_{DD}. According to an example, V_{DD} is about 5V. According to an example, the second voltage is in the range of about 10 mV to about 1V. The lower limit of this range may also be about 50 mV, or about 100 mV, or about 200 mV and the upper limit may also be about 800 mV, or about 600 mV, or about 400 mV. According to an example, the reference potential 110 is ground potential.

The semiconductor chip 100 may be configured to read out the resistance of the first external resistor 102 in a first step and to read out the resistance of the second external resistor 104 in a subsequent second step. As described in the following, the measured resistance of the first external resistor 102 is used in the second step to accurately read out the second resistance. In this way, a single readout pin (i.e. the second pin 108) can be used to read out both resistance values accurately and in a timely manner.

In the first step, which is schematically shown in FIG. 1B, the first voltage V₁ is applied by the semiconductor chip 100 to the second pin 108, causing a first current I₁ to flow from the second pin 108 through the first resistor 102 to the reference potential 110. On the other hand, no current flows through the second resistor 104 in the first step since the first pin 106 and the second pin 108 are both at the same potential. Therefore, the first current I₁ is the total current flowing through the readout pin (second pin 108).

The first current I₁ flowing through the first external resistor 102 is mirrored internally by the semiconductor chip 100 using e.g. a first current mirror 112. The mirrored current is provided to an analog to digital converter (ADC) 112 of the semiconductor chip 100 to determine a first digital resistance value

$${R}_{o n}^{′}$$

representing a resistance of the first external resistor 102.

In the second step, which is schematically shown in FIG. 1C, the second voltage V₂ is applied to the second pin 108 by the semiconductor chip 100, causing a first component current I₂ to flow from the first pin 106 through the second resistor 104 to the second pin 108. The second voltage V₂ may be different from the reference potential V₀. For example, the second voltage V₂ may be greater than V₀ by about 200 mV. This potential difference between the second pin 108 and the reference potential 110 causes a second component current I₃ to flow from the second pin 108 through the first resistor 102 to the reference potential 110. In order to accurately determine the resistance of the second external resistor 104, it is therefore not enough to measure I₂ but it is also necessary to apply an error correction which takes into account the presence of the second component current I₃. This error correction can be performed by the semiconductor chip 100 because the first digital resistance value

$${R}_{o n}^{′}$$

which represents the resistance of the first external resistor 102 is already known from the first step of the measurement procedure.

The need for this error correction could be avoided if the second component current Is was not present. However, it might not be practical to set the second pin 108 equal to the reference potential (i.e. equal to ground potential in the case that the reference potential is ground potential) and thereby eliminate 13. This is because this would require a negative charge pump which would cost chip area and current consumption and which would increase startup time of the system as a whole.

The total second current flowing through the second pin 108 (which is I₂-I₃) is mirrored internally by the semiconductor chip 100 using e.g. a second current mirror 116. The mirrored current is provided to the ADC 114 and an error correction current generated based on the first digital resistance value

$${R}_{o n}^{′}$$

is added to the internally mirrored current to determine a second digital resistance value

$${R}_{off}^{′}$$

representing a resistance of the second external resistor 104. In other words, the error correction current adds the calculated value of the missing second component current Is to the mirrored current such that the resistance value of the second external resistor 104 can be correctly measured despite the presence of the second component current I₃.

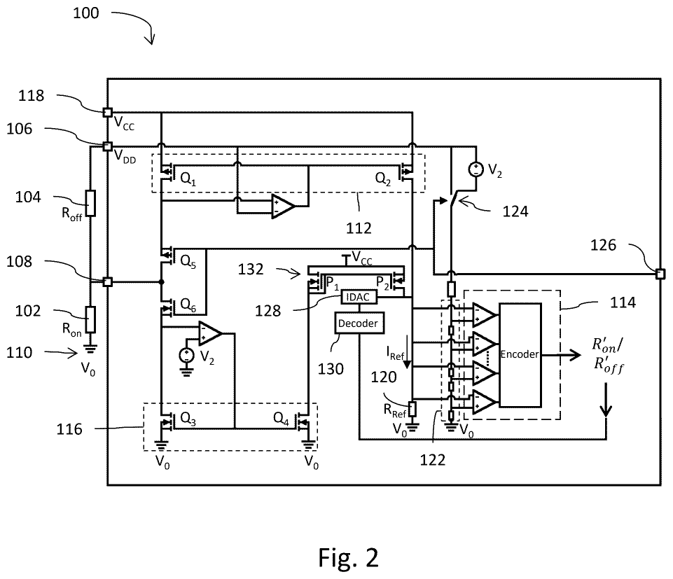

In FIG. 2, an implementation of the semiconductor chip 100 according to an example is shown. Other examples may be used to perform the above-described readout of the resistance values of the first and second external resistors 102, 104.

According to the example shown in FIG. 2, the semiconductor chip 100 comprises a third pin 118 configured to be connected to a supply voltage (V_{CC} in this example). Furthermore, in this example the first voltage of the first pin 106 is V_{DD}, wherein V_{DD}<V_{CC}. According to an example, V_{CC} may be fed to a low dropout regulator (LDO) and V_{DD} may be the output of the LDO. As mentioned further above, V_{CC} could for example also be provided by using a charge pump to boost V_{DD}.

The first current mirror 112 of the example shown in FIG. 2 comprises a first transistor Q₁ and a second transistor Q₂ and the second current mirror 116 comprises a third transistor Q₃ and a fourth transistor Q₄. The first and second current mirrors 112, 116 are connected to a reference resistor (R_{Ref}) 120 such that a mirrored current I_{Ref} can flow through the reference resistor 120. The reference resistor 120 is connected to a voltage divider 122 which in turn feeds the ADC 114. Note that the ADC 114 of the example shown in FIG. 2 is a flash ADC. The semiconductor chip 100 further comprises a fifth transistor Q₅ and a sixth transistor Q₆ which are turned on and turned off depending of which one of the external resistors 102, 104 is to be measured. Furthermore, a switch 124 is set to a first position or a second position depending of which one of the external resistors 102, 104 is to be measured. Also note that in the example of FIG. 2 the reference potential V₀ is ground potential.

Reading out the resistances of the first and second external resistors 102, 104 using the exemplary circuit shown in FIG. 2 may work as follows:

The first step, which comprises measuring the resistance of the first external resistor 102, may be initiated when the semiconductor chip 100 receives a corresponding control signal, for example via a fourth pin (input pin) 126. This control signal causes the fifth transistor Q₅ to be turned on, the sixth transistor Q₆ to be turned off and the second pin 108 (the measurement pin) to be set to the first voltage V₁ which in this example is equal to V_{DD}. Furthermore, the control signal causes the switch 124 to be set into the first position, such that the voltage divider 122 is connected directly to V_{DD} (this is the opposite position for the switch 124 of what is shown in FIG. 2).

During the first step, the current flowing through the second pin 108 is mirrored internally using the first current mirror 112. As illustrated in FIG. 2, the second pin 108 can be set exactly to V_{DD} because there is V_{CC} present which is the supply voltage of the LDO that generates V_{DD}. This implies that V_{CC} will always be higher than V_{DD} during normal operation and startup. Therefore, there is sufficient voltage to regulate the second pin 108 to V_{DD}. This means that there is no systematic error in the measurement of the resistance of the first external resistor 102 due to a current that would flow through the second external resistor 104 if there was a potential difference between the first pin 106 and the second pin 108.

The mirrored current I_{Ref} causes a voltage V_{ref} over the reference resistor 120 which is dependent on the V_{DD} voltage, as the mirrored current I_{Ref} is also proportional to V_{DD}. As mentioned above, the voltage divider 122, which is used as reference for the ADC 114, is connected also to V_{DD}, thus making the reference also proportional to V_{DD}. Hence, the relationship to V_{DD} cancels out. In other words, a change in V_{DD} during the measurement will not skew the result (the measurement may in particular be performed during startup, while V_{DD} is still rising):

$${V}_{R e f} = \frac{{V}_{D D}}{{R}_{o n}} \cdot {R}_{R e f}$$

Using the voltage divider 122, this is compared to

$${V}_{R e f} = \frac{{R}_{X}}{{R}_{t o t}} \cdot {V}_{D D} ,$$

therefore

$${R}_{X} = \frac{{R}_{tot}}{{R}_{on}} .$$

Herein, Rₜₒₜ to this total resistance of the resistor ladder of the voltage divider 122 connected to V_{DD} and Rx is the equivalent resistance that generates the voltage equal to V_{Ref} on this voltage divider 122.

The resistances of the external resistors 102, 104 may for example be chosen from 16 different values and the flash ADC 114 converts the mirrored current into one of the 16 digital values for the resistances that are to be selected. This is the first digital resistance

$${R}_{o n}^{′}$$

output by the ADC 114. The first digital resistance

$${R}_{o n}^{′}$$

may for example be a three bit value or a four bit value or a five bit value.

According to an example, the reference resistor 120 is a trimmed resistor because the resistance of the reference resistor 120 needs to be very accurate in order to read out the resistances of the first and second external resistors 102, 104 with the desired accuracy.

The second step (i.e. the measurement of the resistance of the second external resistor 104) is initiated by sending a corresponding control signal to the fourth pin 126. This causes the fifth transistor Q₅ to be turned off, the sixth transistor Q₆ to be turned on and the switch 124 to be switched to the second position (this position is shown in FIG. 2). In the second position of the switch 124, the voltage divider is connected to V_{DD}-V₂. Furthermore, the second pin 108 is set to the second voltage V₂ (which may for example be 200 mV). As noted above with respect to FIG. 1, this is done because the second pin 108 cannot be regulated down to ground potential without a negative charge pump which would cost chip area, current consumption and startup time.

However, as also noted further above, this now introduces a systematic error of V₂/R_{ON} into the measurement. Nonetheless, the resistance of the first external resistor 102 is known with great accuracy from the measurement in the first step. Therefore, the error introduced into the measurement of R_{off} due to V₂ being higher than V₀ can be removed by taking the first digital resistance

$${R}_{o n}^{′}$$

and providing this value to a current digital to analog converter (IDAC) 128 via a decoder 130. The IDAC 128 adds the required correction to the mirrored current that is being drawn from the second pin 108. This error corrected current is then sent through the reference resistor 120. Since V₂ is used instead of ground, it is necessary to remove the same amount of voltage V₂ from V_{DD}. Mathematically, this can be expressed as follows:

$${I}_{108} = \frac{{V}_{D D} - {V}_{2}}{{R}_{off}} - \frac{{V}_{2}}{{R}_{o n}} ,$$

wherein I₁₀₈ is the current flowing through the second pin 108,

$$\frac{{V}_{D D} - {V}_{2}}{{R}_{off}}$$

is the portion or the current flowing through the second external resistor 104 (i.e. the first component current I₂, compare FIG. 1C) and

$$\frac{{V}_{2}}{{R}_{o n}}$$

is the portion of the current flowing through the first external resistor 102 (i.e. the second component current I₃).

The current that is fed into the reference resistor 120 is:

$${I}_{R e f} = \frac{{V}_{D D} - {V}_{2}}{{R}_{off}} - \frac{{V}_{2}}{{R}_{o n}} + {( \frac{{V}_{2}}{{R}_{o n}} )}_{IDAC} ,$$

wherein the last part

$${( \frac{{V}_{2}}{{R}_{o n}} )}_{IDAC}$$

is the error correction current provided by the IDAC 128. The voltage V_{Ref} over the reference resistor 120 generated by the current I_{Ref} is compared to the voltage divider 122, which requires that V₂ is subtracted from V_{DD} (this is why the switch 124 is now in the second position):

$${I}_{R e f} = \frac{{V}_{D D} - {V}_{2}}{{R}_{off}} = \frac{( {V}_{D D} - {V}_{2} ) \cdot {R}_{X}}{{R}_{t o t}} ,$$

therefore

$${R}_{X} = \frac{{R}_{t o t}}{{R}_{off}} .$$

In other words, the second digital resistance value

$${R}_{off}^{′} ,$$

which is output by the ADC 114 in the second step of the measurement, is inversely proportional to the result Rx obtained from the voltage divider 122.

As shown in the example of FIG. 2, the second current mirror 116 may be connected to a third current mirror 132 which comprises a seventh transistor P₁ and an eighth transistor P₂. The third current mirror 132 may be used to provide the mirrored current in the reference resistor 120 with the same polarity as the current in the second external resistor 104.

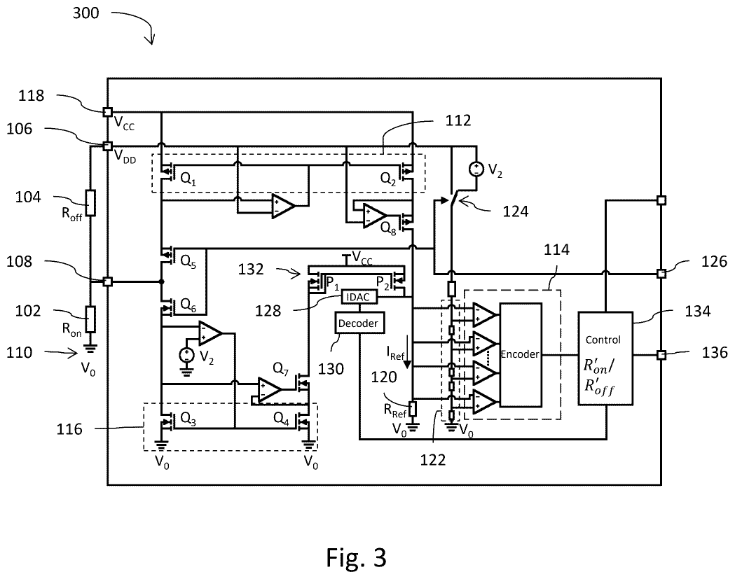

FIG. 3 shows a further electrical circuit comprising a semiconductor chip 300 which may be similar or identical to the semiconductor chip 100, except for the differences described in the following. In particular, the electrical circuit realized in the semiconductor chip 300 may comprise all components described with respect to FIG. 2 and the electrical circuit of the semiconductor chip 300 may comprise some additional components.

The semiconductor chip 300 may for example comprise a ninth transistor Q₇ and a tenth transistor Q₈. The fourth transistor Q₄ and the ninth transistor Q₇ may form a controlled cascode and the second transistor Q₂ and the tenth transistor Q₈ may form another controlled cascode. This implementation may make the first and second current mirrors 112, 114 more accurate.

The semiconductor chip 300 may comprise a control 134 configured to receive the first and second digital resistance values

$${R}_{o n}^{′} and {R}_{off}^{′}$$

from the ADC 114. The control 134 may be connected to the decoder 130 and thereby to the IDAC 128 in order to provide the error correction current to the mirrored current during the second step of the measurement. The control 134 may also be connected to a fifth pin 136, wherein the fifth pin 136 is configured as an output of the measurement circuit (i.e. the first and second digital resistance values

$${R}_{o n}^{′} and {R}_{off}^{′}$$

are provided to the fifth pin 136).

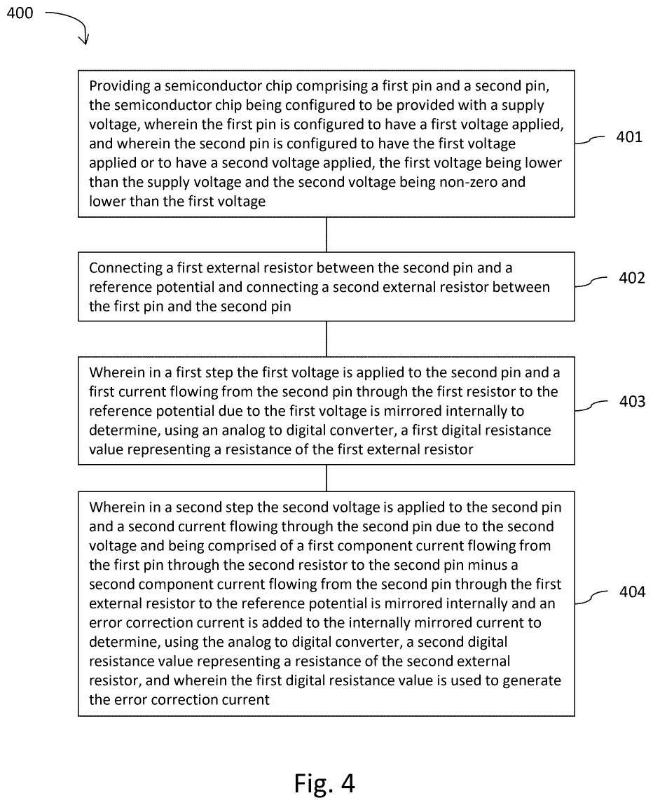

FIG. 4 is a flow chart of an exemplary method 400 for measuring digital resistance values. The method 400 may for example be performed using the external resistors 102, 104 and the semiconductor chip 100 or 300 described above.

The method 400 comprises at 401 a process of providing a semiconductor chip comprising a first pin and a second pin, the semiconductor chip being configured to be provided with a supply voltage, wherein the first pin is configured to have a first voltage applied, and wherein the second pin is configured to have the first voltage applied or to have a second voltage applied, the first voltage being lower than the supply voltage and the second voltage being non-zero and lower than the first voltage; method 400 comprises at 402 a process of connecting a first external resistor between the second pin and a reference potential and connecting a second external resistor between the first pin and the second pin; method 400 comprises at 403 a first step, wherein in the first step the first voltage is applied to the second pin and a first current flowing from the second pin through the first resistor to the reference potential due to the first voltage is mirrored internally to determine, using an analog to digital converter, a first digital resistance value representing a resistance of the first external resistor; and method 400 comprises at 404 a second step, wherein in the second step the second voltage is applied to the second pin and a second current flowing through the second pin due to the second voltage and being comprised of a first component current flowing from the first pin through the second resistor to the second pin minus a second component current flowing from the second pin through the first external resistor to the reference potential is mirrored internally and an error correction current is added to the internally mirrored current to determine, using the analog to digital converter, a second digital resistance value representing a resistance of the second external resistor, and wherein the first digital resistance value is used to generate the error correction current.

FIG. 5 is a flow chart of a method 500 for programming a turn on speed and a turn off speed of an integrated power switch. The method 500 comprises at 501 a process of measuring digital resistance values and at 502 a process of programming a turn on slew rate and a turn off slew rate of the integrated power switch using the first and second digital resistance values. The process 501 of measuring digital resistance values may for example be performed using the methods and devices described with respect to FIGS. 1A-4.

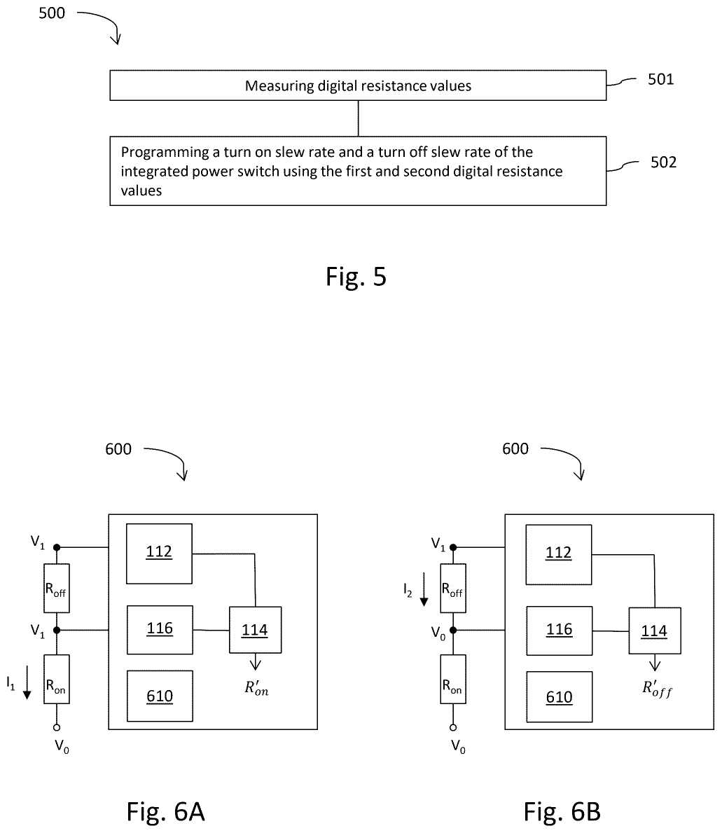

FIGS. 6A and 6B schematically show a further electrical circuit comprising a semiconductor chip 600, the first external resistor 102 (Rₒₙ) and the second external resistor 104 (R_{off}) electrically connected to each other. The semiconductor chip 600 may be similar or identical to the semiconductor chip 100 or 300, except for the differences described in the following.

In particular, with respect to the semiconductor chips 100 and 300, it was assumed that for the second step of measuring the second external resistor 104 (R_{off}), the second voltage V₂ is different from the reference potential 110 (V₀). This causes the second component current I₃ which has to be taken into account when measuring R_{off} (compare e.g. FIGS. 1B and 1C). The semiconductor chip 600 on the other hand is configured to set V₂ equal to V₀, thereby eliminating the second component current I₃. Therefore, when using the semiconductor chip 600, the error correction which is required for the semiconductor chips 100 and 300 does not have to be performed during the second step of the measurement procedure.

According to an example, the reference potential V₀ is ground potential. As already noted further above, a charge pump may for example be used to set V₂ equal to V₀. FIG. 6A shows the first step of determining the first digital resistance value

$${R}_{o n}^{′}$$

as e.g. described in detail with respect to FIG. 2. FIG. 6B shows the second step of determining the second digital resistance value

$${R}_{off}^{′} .$$

The semiconductor chip 600 comprises a charge pump 610 in order to set V₂ equal to V₀ for this second step. Since the error correction of the semiconductor chips 100 and 300 is unnecessary, the semiconductor chip 600 may not require the hardware relating to this error correction, e.g. the IDAC 128, the decoder 130 and the third current mirror 132 (compare FIGS. 2 and 3).

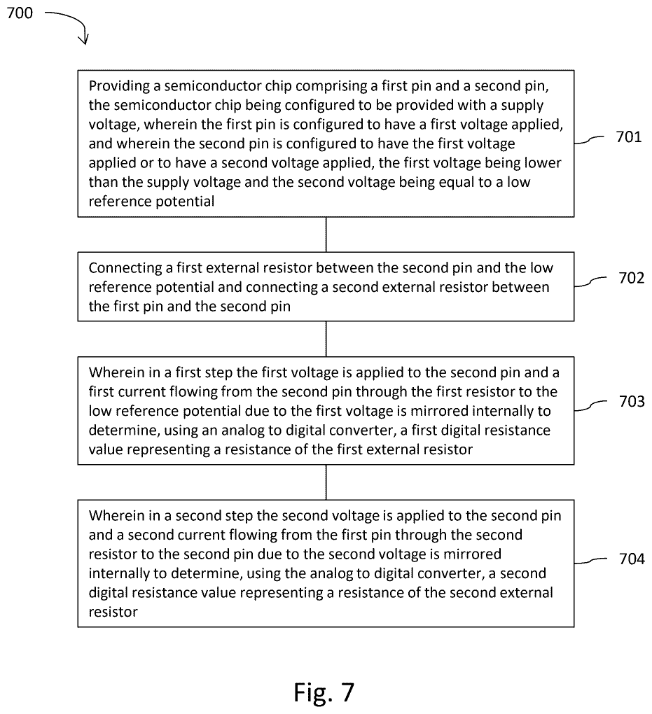

FIG. 7 is a flow chart of an exemplary method 700 for measuring digital resistance values. The method 700 may for example be performed using the external resistors 102, 104 and the semiconductor chip 600.

The method 700 comprises at 701 a process of providing a semiconductor chip comprising a first pin and a second pin, the semiconductor chip being configured to be provided with a supply voltage, wherein the first pin is configured to have a first voltage applied, and wherein the second pin is configured to have the first voltage applied or to have a second voltage applied, the first voltage being lower than the supply voltage and the second voltage being equal to a reference potential; method 700 comprises at 702 a process of connecting a first external resistor between the second pin and the reference potential and connecting a second external resistor between the first pin and the second pin; method 700 comprises at 703 a first step, wherein in the first step the first voltage is applied to the second pin and a first current flowing from the second pin through the first resistor to the reference potential due to the first voltage is mirrored internally to determine, using an analog to digital converter, a first digital resistance value representing a resistance of the first external resistor; method 700 comprises at 704 a second step, wherein in the second step the second voltage is applied to the second pin and a second current flowing from the first pin through the second resistor to the second pin due to the second voltage is mirrored internally to determine, using the analog to digital converter, a second digital resistance value representing a resistance of the second external resistor.

According to an example, the supply voltage is provided to the semiconductor chip externally (compare also FIGS. 2 and 3). According to another example, the supply voltage may be provided internally, using e.g. a charge pump to boost the first voltage, wherein the first voltage is provided externally. According to an example, a charge pump may be used to set the second voltage equal to the reference potential, e.g. equal to ground potential.

Compared to the semiconductor chips 100 and 300, respectively the measurement method 400, the semiconductor chip 600, respectively the method 700 may require more startup time and/or more chip area (for the charge pump) and/or may exhibit a higher current consumption.

As previously discussed, the circuit in FIG. 3 enables high accuracy and fast resistor measurement of 2 external resistors R_{off} and Rₒₙ connected to power input node 108. One potential issue that may arise in the circuit 300 is that a noise disturbance may occur while the resistive measurements of resistors R_{off} and Rₒₙ are being performed, which may result in a false or inaccurate resistor magnitude determination.

One type of possible noise disturbance that may occur during startup is a so-called CMTI (Common Mode Transient Immunity) pulse on the source of the High Side Driver. An additional noise disturbance can occur if the LLC converter configuration is used where, after the low side switches OFF, an oscillation of the resonator frequency may be present on the source of the High Side switch of the half bridge.

These noise disturbances may be mainly coupled to the RDD pin (a.k.a., pin 108) via a parasitic capacitance between the semiconductor package (300) and the pin 108 itself. This noise may cause the current sense transistors Q3 and Q1 to exit their normal operating mode, thus, simply adding a low pass filter may not fix the issue. An example solution is further discussed below

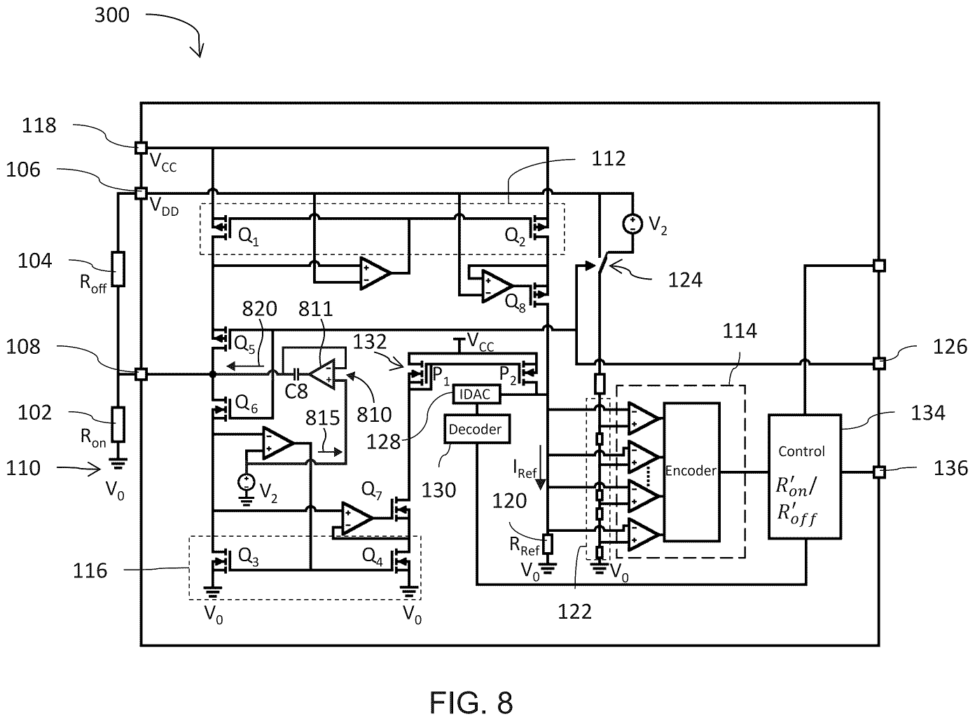

FIG. 8 is an example diagram illustrating implementation of noise canceling circuitry as discussed herein.

One example of the circuit 300 as discussed herein may include noise cancellation circuitry 810 such as including a noise cancellation op-amp 811 (operational-amplifier) as illustrated in FIG. 8, where the noise cancellation circuitry 810 (such as operational amplifier 811 in capacitor C8) injects a respective current (such as noise cancellation signal 820) to the node RDD, where the noise cancellation signal 820 is opposite in phase with respect to the noise received into the RDD pin 108. The implementation of the noise cancellation circuitry 810 enables the current sense transistors in the circuit 300 to remain in normal operating mode because the noise disturbances on these devices as a result of noise cancellation are now significantly lower during either pulse or oscillation disturbances, thus enabling low-pass filtering. The injection of the ac current (a.k.a., noise cancellation signal 820) back through the capacitor means that the DC accuracy measurement of the circuitry 300 is not affected.

Accordingly, the noise cancellation as discussed herein is made with a simple operational amplifier or OTA that couples the noise back into the RDD pin via a capacitor C8 with opposite phase. This capacitor C8 is present to block DC signals so that the output of the noise cancellation signal from the operational amplifier 811 does not impact the DC accuracy of the sensing circuitry. By removing the DC connection and the ac noise via the noise cancellation signal 820, the transistor Q9/Q13 now still might have some left over noise but not enough to have them exit saturation. This enables the circuit 300 to use averaging or using low pass filters to improve further noise immunity.

The techniques as discussed herein enable the saving of a pin on the circuit 300 by measuring resistances of 2 resistors (Roff and Ron) even if the measurement happens to occur during a noise disturbance.

Thus, one aspect as discussed herein is to feed into the pin 108 (a.k.a., pin RDD), which is being disturbed, an equal and opposite disturbance via the noise cancellation signal 820 delivered from a capacitor C8 of the noise cancellation circuitry 810 to enable a more accurate resistor readout despite CMTI and/or sinusoidal noise injection via parasitic.

Accordingly, the electrical circuit as discussed herein in FIG. 8 may include: a noise cancellation circuit 810 operative to supply a noise cancellation signal 820 to the pin 108 (a.k.a., circuit node).

The noise cancellation circuit 810 can be configured to receive a noise signal 815 (such as an AC or alternating voltage signal) from the reference potential or other source. The noise cancellation circuit 810 inverts the received noise signal 815 (such as AC noise portion, where the capacitor C8 blocks the DC voltage from the received noise signal 815) to produce the noise cancellation signal 820 applied to the pin 108. As previously discussed, the noise cancellation circuit 810 can be configured to receive the noise signal 815 from a reference potential Vo (a.k.a., V_0) or other voltage source such as V2 (such as 400 millivolts or other suitable voltage).

Additionally, it is note that the circuit 300 includes: a first circuit node (pin 108) coupling a first resistor Ron and a second resistor Roff in series between an input voltage source and a reference voltage source; current mirror circuitry coupled to monitor the first circuit node (108), the current mirror circuitry operative to: i) produce a first mirror current based a first current conveyed through the first resistor, and ii) produce a second mirror current based on a second current conveyed through the second resistor; and measurement circuitry operative to determine resistances of the first resistor and the second resistor based at least in part on monitoring of the first circuit node (pin 108). The implementation of the circuit 300 as discussed herein may reduce the number of pins required in the circuit 300 to determine the resistances of the first resistor and the second resistor.

### EXAMPLES

In the following, the electrical circuit, the method for determining electrical resistor values and the method for programming a turn on speed and a turn off speed of an integrated power switch are further explained using specific examples.

Example 1 is a method for measuring digital resistance values, the method comprising: providing a semiconductor chip comprising a first pin and a second pin, the semiconductor chip being configured to be provided with a supply voltage, wherein the first pin is configured to have a first voltage applied, and wherein the second pin is configured to have the first voltage applied or to have a second voltage applied, the first voltage being lower than the supply voltage and the second voltage being non-zero and lower than the first voltage, connecting a first external resistor between the second pin and a reference potential and connecting a second external resistor between the first pin and the second pin, wherein in a first step the first voltage is applied to the second pin and a first current flowing from the second pin through the first external resistor to the reference potential due to the first voltage is mirrored internally to determine, using an analog to digital converter, a first digital resistance value representing a resistance of the first external resistor, wherein in a second step the second voltage is applied to the second pin and a second current flowing through the second pin due to the second voltage and being comprised of a first component current flowing from the first pin through the second resistor to the second pin minus a second component current flowing from the second pin through the first external resistor to the reference potential is mirrored internally and an error correction current is added to the internally mirrored current to determine, using the analog to digital converter, a second digital resistance value representing a resistance of the second external resistor, and wherein the first digital resistance value is used to generate the error correction current.

Example 2 is the method of example 1, wherein the mirrored first or second current flows through a trimmed reference resistor and thereby generates a reference voltage, wherein the reference voltage is dependent on the first voltage, and wherein the reference voltage is used to generate the first and second digital resistance values in the analog to digital converter.

Example 3 is the method of example 2, wherein the reference resistor is connected to the reference potential.

Example 4 is the method of example 2 or 3, wherein generating the error correction current comprises feeding the first digital resistance value into a feedback loop.

Example 5 is the method of example 4, wherein the feedback loop comprises a decoder and a current digital to analog converter configured to output the error correction current based on the first digital resistance value.

Example 6 is the method of example 5, further comprising: adding the error correction current output by the digital to analog converter to the mirrored second current flowing through the reference resistor.

Example 7 is the method of one of the preceding examples, wherein the error correction current is equal to the reference potential divided by the first digital resistance value.

Example 8 is the method of one of the preceding examples, wherein the semiconductor chip comprises a first current mirror to mirror the first current and a different second current mirror to mirror the second current.

Example 9 is a method for programming a turn on and turn off speed of an integrated power switch, the method comprising: performing the method for measuring digital resistance values according to one of the preceding examples, and programming a turn on slew rate and a turn off slew rate of the integrated power switch using the first and second digital resistance values.

Example 10 is the method of example 9, wherein the integrated power switch is a GaN device or a SiC device or a MOSFET device.

Example 11 is an electrical circuit configured for measuring digital resistance values, the circuit comprising: a semiconductor chip comprising a first and a second pin, wherein the semiconductor chip is configured to be provided with a supply voltage, wherein the first pin is configured to have a first voltage applied, and wherein the second pin is configured to have the first voltage applied or to have a second voltage applied, the first voltage being lower than the supply voltage and the second voltage being non-zero and lower than the first voltage, a first external resistor connected between the second pin and a reference potential and a second external resistor connected between the first pin and the second pin, wherein the electrical circuit is configured to have in a first step the first voltage applied to the second pin and to mirror internally a first current flowing from the second pin through the first external resistor to the reference potential due to the first voltage in order to determine, using an analog to digital converter, a first digital resistance value representing a resistance of the first external resistor, wherein the electrical circuit is configured to have in a second step the second voltage applied to the second pin and to mirror internally a second current flowing through the second pin due to the second voltage and being comprised of a first component current flowing from the first pin through the second resistor to the second pin minus a second component current flowing from the second pin through the first external resistor to the reference potential in order to determine, using the analog to digital converter, a second digital resistance value representing a resistance of the second external resistor, wherein the first digital resistance value is used to generate the error correction current.

Example 12 is the electrical circuit of example 11, further comprising: a low dropout regulator, wherein the supply voltage is supplied to the low dropout regulator and the second voltage is output by the low dropout regulator.

Example 13 is the electrical circuit of example 11 or 12, wherein the semiconductor chip further comprises an input pin configured to receive a signal, wherein based on the signal the electrical circuit switches between performing the first step and performing the second step.

Example 14 is the electrical circuit of one of examples 11 to 13, wherein the semiconductor chip further comprises an output pin, wherein the first and second digital resistance values are provided to the output pin.

Example 15 is an electrical circuit configured for measuring digital resistance values, the circuit comprising: a semiconductor chip comprising a first and a second pin, wherein the semiconductor chip is configured to be provided with a supply voltage, wherein the first pin is configured to have a first voltage applied, and wherein the second pin is configured to have the first voltage applied or to have a second voltage applied, the first voltage being lower than the supply voltage and the second voltage being equal to a reference potential, a first external resistor connected between the second pin and the reference potential and a second external resistor connected between the first pin and the second pin, wherein the electrical circuit is configured to have in a first step the first voltage applied to the second pin and to mirror internally a first current flowing from the second pin through the first external resistor to the reference potential due to the first voltage in order to determine, using an analog to digital converter, a first digital resistance value representing a resistance of the first external resistor, wherein the electrical circuit is configured to have in a second step the second voltage applied to the second pin and to mirror internally a second current flowing from the first pin through the second resistor to the second pin due to the second voltage in order to determine, using the analog to digital converter, a second digital resistance value representing a resistance of the second external resistor.

Example 16 is the electrical circuit of example 15, wherein the semiconductor chip comprises a charge pump to set the second voltage equal to the reference potential.

Example 17 is a method for measuring digital resistance values, the method comprising: providing a semiconductor chip comprising a first pin and a second pin, the semiconductor chip being configured to be provided with a supply voltage, wherein the first pin is configured to have a first voltage applied, and wherein the second pin is configured to have the first voltage applied or to have a second voltage applied, the first voltage being lower than the supply voltage and the second voltage being equal to a reference potential, connecting a first external resistor between the second pin and a reference potential and connecting a second external resistor between the first pin and the second pin, wherein in a first step the first voltage is applied to the second pin and a first current flowing from the second pin through the first external resistor to the reference potential due to the first voltage is mirrored internally to determine, using an analog to digital converter, a first digital resistance value representing a resistance of the first external resistor, wherein in a second step the second voltage is applied to the second pin and a second current flowing from the first pin through the second resistor to the second pin due to the second voltage is mirrored internally to determine, using the analog to digital converter, a second digital resistance value representing a resistance of the second external resistor.

Example 18 is the method of example 17, wherein in the second step a charge pump of the semiconductor chip is used to set the second voltage equal to the reference potential.

Example 19 is a method for programming a turn on and turn off speed of an integrated power switch, the method comprising: performing the method for measuring digital resistance values according to one of examples 17 or 18, and programming a turn on slew rate and a turn off slew rate of the integrated power switch using the first and second digital resistance values.

Example 20 is the method of example 19, wherein the integrated power switch is a GaN device or a SiC device or a MOSFET device.

Example 21 is an apparatus comprising means for performing the method according to anyone of examples 1 to 10 and 17 to 20.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

1. A method for measuring digital resistance values, the method comprising:
providing a semiconductor chip comprising a first pin and a second pin, the semiconductor chip being configured to receive a supply voltage, wherein the first pin is configured to receive a first voltage, and wherein the second pin is configured to receive the first voltage applied or received a second voltage, the first voltage being lower than the supply voltage and the second voltage being non-zero and lower than the first voltage,
connecting a first external resistor between the second pin and a reference potential and connecting a second external resistor between the first pin and the second pin,
wherein, in a first operation, the first voltage is applied to the second pin and a first current flowing from the second pin through the first external resistor to the reference potential due to the first voltage is mirrored internally to determine, using an analog to digital converter, a first digital resistance value representing a resistance of the first external resistor,
wherein, in a second operation, the second voltage is applied to the second pin and a second current flowing through the second pin due to the second voltage and the second current being comprised of a first component current flowing from the first pin through the second resistor to the second pin minus a second component current flowing from the second pin through the first external resistor to the reference potential, where the second current is mirrored and an error correction current is added to the mirrored current to determine, using the analog to digital converter, a second digital resistance value representing a resistance of the second external resistor, and
wherein the first digital resistance value is used to generate the error correction current.

2. The method of claim 1, wherein the mirrored first or second current flows through a trimmed reference resistor and thereby generates a reference voltage, wherein the reference voltage is dependent on the first voltage, and wherein the reference voltage is used to generate the first and second digital resistance values in the analog to digital converter.

3. The method of claim 2, wherein the reference resistor is connected to the reference potential.

4. The method of claim 2, wherein generating the error correction current comprises feeding the first digital resistance value into a feedback loop.

5. The method of claim 4, wherein the feedback loop comprises a decoder and a current digital to analog converter configured to output the error correction current based on the first digital resistance value.

6. The method of claim 5, further comprising: adding the error correction current output by the digital to analog converter to the mirrored second current flowing through the reference resistor.

7. The method of claim 1, wherein the error correction current is equal to the reference potential divided by the first digital resistance value.

8. The method of claim 1, wherein the semiconductor chip comprises a first current mirror to mirror the first current and a different second current mirror to mirror the second current.

9. A method for programming a turn on and turn off speed of an integrated power switch, the method comprising:
performing the method for measuring digital resistance values according to claim 1, and
programming a turn on slew rate and a turn off slew rate of the integrated power switch using the first and second digital resistance values.

10. The method of claim 9, wherein the integrated power switch is a GaN device or a SiC device or a MOSFET device.

11. (canceled)

12. (canceled)

13. (canceled)

14. (canceled)

15. An electrical circuit operative to measure digital resistance values, the electrical circuit comprising:
a semiconductor chip comprising a first pin and a second pin, wherein the semiconductor chip is configured to receive a supply voltage, wherein the first pin is configured to receive a first voltage applied, and wherein the second pin is configured to receive the first voltage or receive a second voltage, the first voltage being lower than the supply voltage and the second voltage being equal to a reference potential,
a first external resistor connected between the second pin and the reference potential and a second external resistor connected between the first pin and the second pin,
wherein the electrical circuit is further configured to, in a first operation, receive the first voltage at the second pin and to mirror internally a first current flowing from the second pin through the first external resistor to the reference potential due to the first voltage in order to determine, using an analog to digital converter, a first digital resistance value representing a resistance of the first external resistor,
wherein the electrical circuit is configured to, in a second operation, receive the second voltage at the second pin and to mirror internally a second current flowing from the first pin through the second resistor to the second pin due to the second voltage in order to determine, using the analog to digital converter, a second digital resistance value representing a resistance of the second external resistor.

16. The electrical circuit of claim 15, wherein the semiconductor chip comprises a charge pump to set the second voltage equal to the reference potential.

17. The electrical circuit of claim 15 further comprising:
a noise cancellation circuit operative to supply a noise cancellation signal to the second pin.

18. The electrical circuit of claim 17, wherein the noise cancellation circuit is operative to:
receive a noise signal; and
invert the noise signal to produce the noise cancellation signal.

19. The electrical circuit of claim 18, wherein the noise cancellation circuit is operative to receive the noise signal from the reference potential.

20. An apparatus comprising:
a first circuit node coupling a first resistor and a second resistor in series between an input voltage source and a reference voltage source;
current mirror circuitry coupled to monitor the first circuit node, the current mirror circuitry operative to: i) produce a first mirror current based a first current conveyed through the first resistor, and ii) produce a second mirror current based on a second current conveyed through the second resistor; and
measurement circuitry operative to determine resistances of the first resistor and the second resistor based at least in part on monitoring of the first circuit node.
